(19) United States
(12) Patent Application Publication
(10) Pub. No.: US 2025/0263843 A1
(43) Pub. Date: Aug. 21, 2025

(54) ELECTRODE AND CIRCUITRY DESIGN FOR CORROSION PROTECTION IN LIQUID COOLING SYSTEM

(71) Applicant: Cisco Technology, Inc., San Jose, CA (US)

(72) Inventors: Vipulkumar K. PATEL, Breinigsville, PA (US); Chun Chih CHEN, Hsinchu City (TW); Huan Chun CHEN, New Taipei City (TW); Glen Michael J. BROOKS, San Jose, CA (US)

(21) Appl. No.: 18/443,076

(22) Filed: Feb. 15, 2024

(51) Int. Cl. C23F 13/04; C23F 13/22; H01L 23/473; H05K 7/20

(52) U.S. Cl. CPC C23F 13/04; C23F 13/22; H01L 23/473; H05K 7/20218

(57) ABSTRACT

Embodiments herein describe liquid cooling systems and methods that measure a current between an inert counter electrode and a non-inert heat exchange component. This current can result in corrosion. The liquid cooling system can then apply a voltage (e.g., a reverse bias) that causes current to flow from the counter electrode to the non-inert heat exchange components. The embodiments herein can be used if the liquid cooling system includes heat exchange components that are made of the same non-inert metal or includes heat exchange components made of different metals.

### TECHNICAL FIELD

Embodiments presented in this disclosure generally relate to preventing corrosion in liquid cooling systems. More specifically, embodiments disclosed herein use a counter electrode to reduce corrosion.

### BACKGROUND

As computer systems and the associated electronic devices increase in power and complexity, the heat output of these systems also increases. While traditional air flow based cooling systems provide some levels of cooling, liquid cooling systems are increasingly found to provide more direct and efficient cooling paradigms for high powered and high heat producing electronic devices. While development in liquid cooling systems has improved, the related efficiencies and costs of installing and maintaining liquid cooling systems remains challenging.

For example, liquid cooling systems are typically more expensive in time and resource usage compared to the traditional airflow systems. One of the primary causes of the time and resource costs in liquid cooling systems relates to ensuring that liquid coolant in the systems is at appropriate levels in the system and not leaking from the system. Much of this required maintenance and need for liquid replacement and system inspection is due to corrosion that occurs in the liquid cooling systems. Reducing or preventing corrosion in the liquid cooling systems remains a challenge.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIGS. 1-3 illustrates models of liquid cooling systems that include counter electrodes, according to embodiments described herein.

FIG. 4 is a flowchart for mitigating corrosion in a liquid cooling system using a counter electrode, according to one embodiment.

FIG. 5 illustrates a liquid cooling system with a counter electrode, according to one embodiment.

FIG. 6 illustrates an equivalent circuitry for the cooling system in FIG. 5, according to one embodiment.

FIG. 7 illustrates a closed loop liquid cooling system, according to one embodiment.

FIG. 8 illustrates on open loop liquid cooling system, according to one embodiment.

FIG. 9 illustrates a block diagram of a reverse bias system, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a liquid cooling system that includes a first heat exchange component comprising a first non-inert metal, a counter electrode comprising an inert material, piping configured to carry a liquid coolant where the first heat exchange component and the counter electrode contact the liquid coolant, a sensor configured to measure a current flowing, or a voltage, between the first heat exchange component and the counter electrode, and a control system coupled to the sensor and configured to control a power supply electrically connected to the first heat exchange component and the counter electrode to generate a voltage that reduces or prevents current from flowing between the first heat exchange component and the counter electrode.

One embodiment presented in this disclosure is a method that includes measuring current flowing between, or a voltage between, a first heat exchange component and a counter electrode in a liquid cooling system where the first heat exchange component includes a first non-inert metal and the counter electrode includes an inert material. Further, the first heat exchange component and the counter electrode contact a liquid coolant in the liquid cooling system. The method also includes generating a voltage to reduce or prevent current from flowing between the first heat exchange component and the counter electrode.

### Example Embodiments

As described above, liquid cooling systems provide effective cooling to high heat producing electronic devices. However, liquid cooling systems have several intrinsic problems related to the corrosion of the various components in the system over time. Corrosion on the heat exchange components in a liquid cooling system can occur from at least two sources: galvanic corrosion when different types of metals are used in the liquid cooling system, and oxidation. The embodiments herein can be used to minimize or eliminate both types of corrosions by using a counter electrode made from an inert material (e.g., gold, platinum, graphite, silver, etc.).

Some solutions to counteract the corrosion have been implemented to limited success in liquid cooling systems. For example, a corrosion inhibitor may be added to the liquid coolant to slow corrosion; however, these corrosion inhibitors and the related thermal conductivity of the liquid coolant in liquid cooling systems often degrades over time. This degradation may be caused by a degradation of corrosion inhibitors in liquid coolants, temperature induced degradation, or by oxidation in the liquid. This degradation, in turn, requires the liquid to be refilled or replaced frequently, which increases maintenance costs of the liquid cooling system.

The systems and methods described herein can be used with a coolant that includes a liquid inhibitor and coolant that does not. If the coolant includes a liquid inhibitor, the embodiments herein can greatly extend the life of the corrosion inhibitor, and thus, reduce maintenance costs. If the coolant does not include the liquid inhibitor, the embodiments herein can still mitigate corrosion, although perhaps not as well or as long as a coolant that includes liquid inhibitor. In any case, the embodiments herein describe a liquid cooling system that measures currents between the counter electrode and metallic heat exchange components. This current can result in both galvanic corrosion and oxidation. The liquid cooling system can then apply a voltage (e.g., a reverse bias) to reduce or eliminate both galvanic corrosion and oxidation. This control system can be used if the liquid cooling system includes heat exchange components that are the same metal (in which case there is no galvanic corrosion, although there may still be oxidation) or includes heat exchange components of different metals, in which case there can be both galvanic corrosion and oxidation.

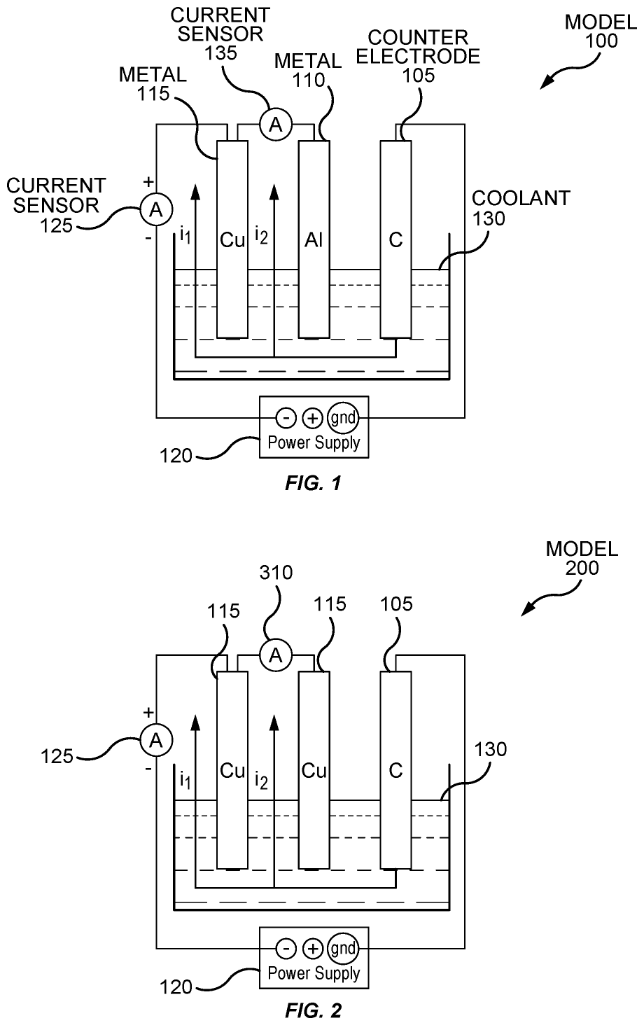

FIGS. 1-3 illustrates models of liquid cooling systems that include counter electrodes, according to embodiments described herein. FIG. 1 illustrates a model 100 of a liquid cooling system that includes two different types of metal that are electrically connected to a counter electrode 105. For example, metal 110 (e.g., aluminum in this example) can represent the material of a first heat exchange component in the liquid cooling system, while metal 115 (e.g., copper in this example) represents the material of a second heat exchange component in the liquid cooling system. The counter electrode 105, the metal 110, and the metal 115 contact a coolant 130 of the liquid cooling system.

Because the metals 110 and 115 are different types of non-inert metals (e.g., aluminum and copper), there can be galvanic corrosion on these metals. In some cases, corrosion is most significant in liquid cooling systems with differing materials due to galvanic corrosion. For example, a cold plate made be made of metal 110 while a radiator is made from metal 115, and as such, may experience large amounts of galvanic corrosion. Homogenous systems, such as copper only based liquid cooling systems avoid this problem of galvanic corrosion, but may have greater fabrication costs, relatively heavy in weight, and suffer from low production yields in manufacturing.

The model 100 also illustrates a power supply 120, a first current sensor 125, and a second current sensor 135. One output of the power supply 120 (e.g., the ground output) is coupled to the counter electrode 105 while another output (e.g., the negative output) is coupled to the metal 115. However, this is just one example of coupling the metal 115 and the counter electrode 105 to the power supply 120.

The first current sensor 125 is disposed in the current path between the metal 115 and the counter electrode 105. In this example, the current sensor 125 is disposed between the metal 115 and the power supply 120 but could also be disposed between the power supply 120 and the counter electrode 105.

The second current sensor 135 is disposed in the current path between the metal 115 and the metal 110.

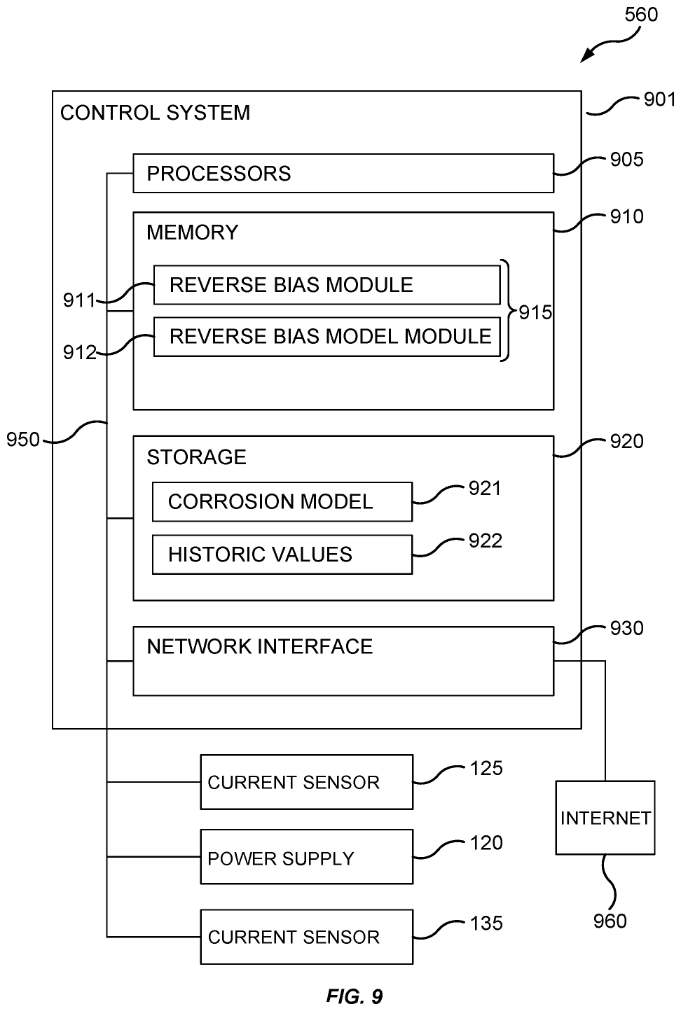

A control system (discussed in detail in FIG. 9) can monitor the current measured by the first current sensor 125 and the second current sensor 135 and control the power supply 120 to generate a voltage that prevents or reduces galvanic corrosion and oxidation. To do so, in one embodiment, the voltage supply generates a reverse bias that causes the current through the metal 115 (i.e., i₁) and the current though the metal 110 (i.e., i₂) to flow in the same direction. That is, the power supply 120 generates a voltage bias that causes current to flow from the counter electrode 105 to the metal 110 and 115 as shown in FIG. 1. Doing so can reduce or prevent galvanic corrosion, as well as oxidation. By adding the counter electrode 105, the surface reactions on the metals 110 and 115 are converted to electrochemical reactions which do not cause corrosion.

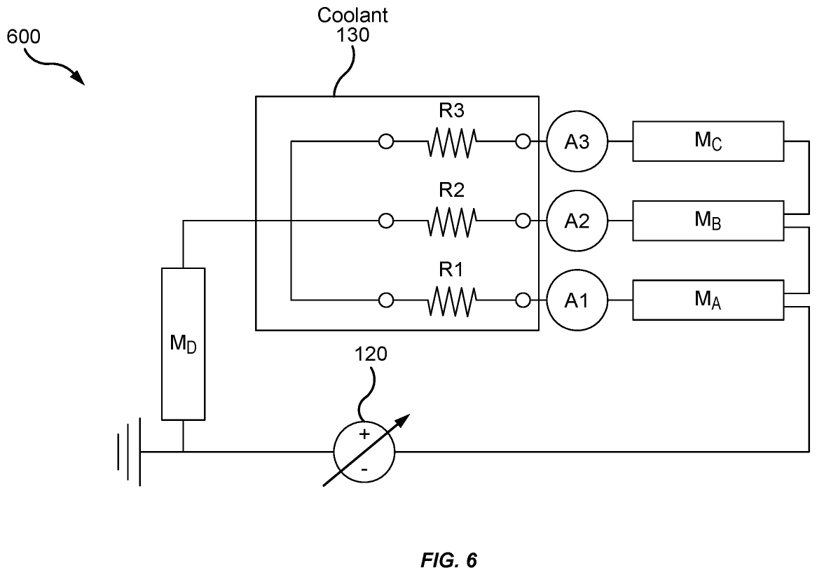

Further, the model 100 illustrates electrically connecting the metal 115 to the metal 110 so that the metal 115 and the metal 110 are at the same voltage potential. However, the metals 110 and 115 may not be connected serially, but rather in parallel with the counter electrode 105 which is shown in FIG. 6.

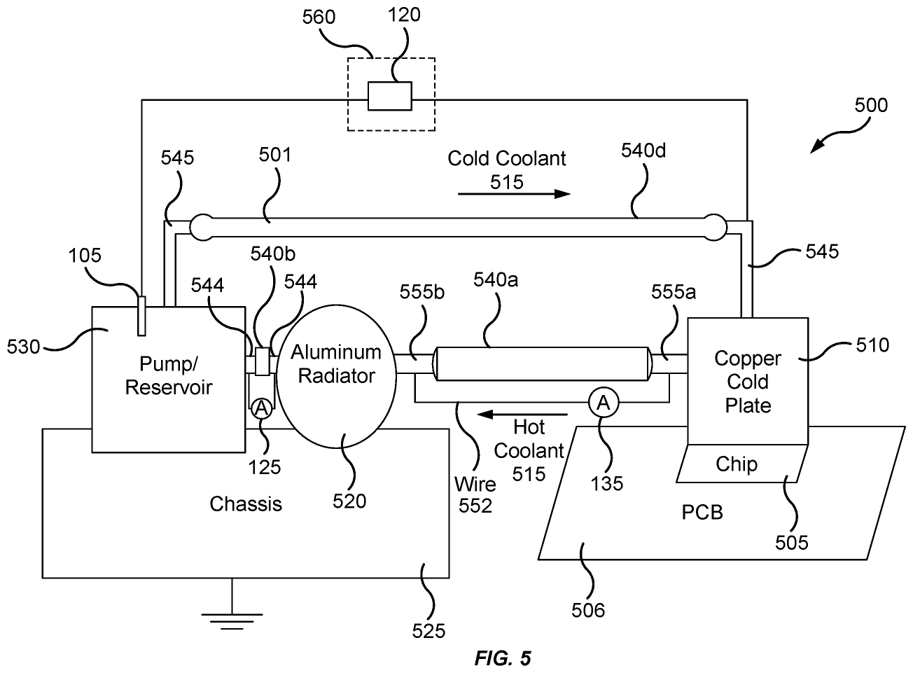

Electrically connecting the metals 110 and 115 to each other represents electrically connecting two heat exchange components (made from different metals) to each other using, e.g., a conductive wire. This is shown in more detail in FIG. 5 below. In another embodiment, because the metals 110 and 115 have the same voltage potential, the power supply 120 could have been coupled to the metal 110 (rather than the metal 115) and the system would function the same to prevent corrosion assuming the same current direction. In one embodiment, wiring that connects the metals 110 and 115 can be a conductive tubing system, such as metal, or an extra connection if non-conductive tubing if used in the cooling system.

FIG. 2 illustrates a model 200 of a liquid cooling system that includes two heat exchange components made from the same metal 115. For example, the two heat exchange components could be a cold plate and a radiator formed using the same metal 115. The two heat exchange components represented by the two instances of metal 115 are connected in the same manner to each other, and to the counter electrode 105, as in FIG. 1. That is, the metals 115 are at the same voltage potential, while one of the metals 115 is connected to the counter electrode 105 through the power supply 120.

Like above, a control system can monitor the current measured by the first current sensor 125 and the second current sensor 135 and control the power supply 120 to generate a voltage that causes the currents through both metals 115 (i.e., i₁ and i₂) to flow in the same direction. Put differently, current flows from the counter electrode 105 to both the metals 115. In this case, doing so can reduce or prevent oxidation. There would be no galvanic corrosion in this instance since the two metals 115 are the same. Thus, the model 200 illustrates that the control system described herein can be used in a liquid cooling system that has any number of heat exchange components made from the same metal. In one embodiment, wiring that connects the metals 115 can be a conductive tubing system, such as metal, or an extra connection if non-conductive tubing if used in the cooling system.

Further still, the control system could be used if the liquid cooling system had only one non-inert heat exchange component and a counter electrode, although most liquid cooling systems have multiple metallic heat exchange components.

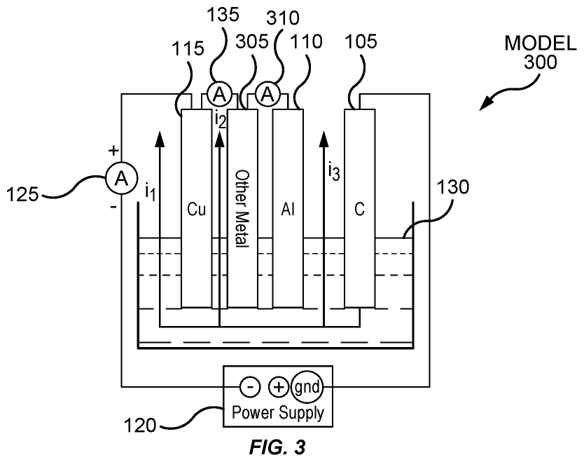

FIG. 3 illustrates a model 300 of a liquid cooling system that includes three heat exchange components made from three different types of non-inert metals. For example, a radiator may be made from metal 115, a cold plate may be made from metal 110, and a pump tank may be made from metal 305. As shown, the three metals 110, 115, and 305 are connected to each other by respective current sensors to measure the current flowing between them. One of the metals (metal 115 in this case) is coupled to the counter electrode 105 via the power supply 120.

Like above, a control system can monitor the current measured by the current sensor 125, the second current sensor 135, and a third current sensor 310 and control the power supply 120 to generate a voltage that causes the current through the metal 115 (i.e., i₁), the current through metal 305 (i.e., i₂), and the current through metal 110 (i.e., i₃) to flow in the same direction. Put differently, current flows from the counter electrode 105 to the metals 110, 115, and 305. Doing so can reduce or prevent galvanic corrosion, as well as oxidation. Thus, the model 300 illustrates that the control system described herein can be used in a liquid cooling system that has any number of heat exchange components made from any number of different non-inert metals. In one embodiment, wiring that connects the metals 110, 115, and 305 can be a conductive tubing system, such as metal, or an extra connection if non-conductive tubing if used in the cooling system.

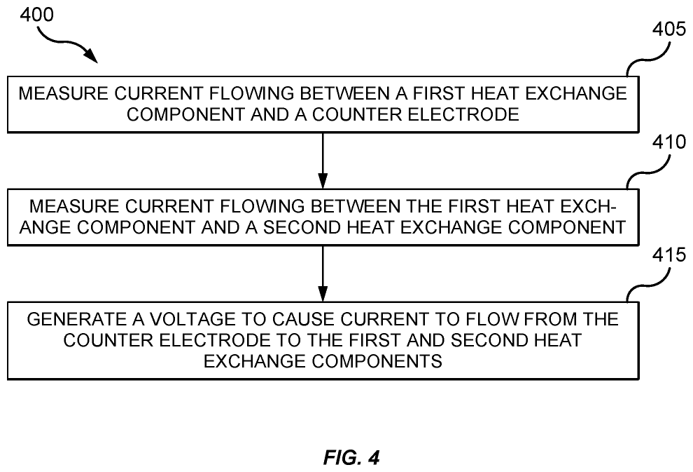

FIG. 4 is a flowchart of a method 400 for mitigating corrosion in a liquid cooling system using a counter electrode, according to one embodiment. At block 405, a first current sensor (e.g., the current sensor 125 in FIGS. 1-3) measures current flowing between a first heat exchange component and a counter electrode. The first heat exchange component can be made from a non-inert metal (e.g., copper, aluminum, etc.) while the counter electrode is made from an inert material (e.g., graphite, gold, platinum, silver, etc.).

At block 410, a second current sensor (e.g., the current sensor 135 in FIGS. 1-3) measures current flowing between the first heat exchange component and a second heat exchange component. The second heat exchange component can be made from a non-inert metal (e.g., copper, aluminum, etc.) which can be the same material as the first heat exchange component, or a different material.

At block 415, a power supply generates a voltage to cause current to flow from the counter electrode to the first and second heat exchange components. In one embodiment, the power supply provides a reserve biased voltage which generates current that flows in the same direction in the first and second heat exchange components. Alternatively, there may be no current flowing through one of the heat exchange components while current does flow from the counter electrode to the other heat exchange component. Doing so can reduce or prevent one of, or both of, galvanic corrosion and oxidation.

In another embodiment, voltage sensing rather than current sensing can be used.

Although method 400 describes using a counter electrode to reduce corrosion for two heat exchange components made from a non-inert metal, the method 400 can be expanded to any number of heat exchange components, whether they are made from the same metal (as shown in FIG. 2) or different metals (as shown in FIGS. 1 and 3). Further, the heat exchange components may be electrically connected via current sensors.

FIG. 5 illustrates a liquid cooling system 500 with a counter electrode 105, according to one embodiment. The system 500 includes a reverse bias system 560 to prevent corrosion in the system 500. The system 500 also includes a coolant pump system such as pump/reservoir 530 and aluminum radiator 520 mounted on a grounded chassis 525. In some examples, the aluminum radiator 520 is an air cooled aluminum radiator. The pump/reservoir 530 receives a coolant 501 from the aluminum radiator 520 via a pipe 540b connected to each respective component via fittings 544. The pump/reservoir 530 stores the coolant and provides the coolant 501 in a cold state to copper cold plate 510 via a pipe 540d. The pipe 540d is connected to the pump system and the copper cold plate 510 via fittings 545.

The copper cold plate 510 provides heat exchange/cooling to a chip 505 mounted on a printed circuit board (PCB) 506. As the coolant 501 flows along direction 515 into the copper cold plate 510, the coolant is heated such that the coolant 501 flows from the copper cold plate 510 to the aluminum radiator 520 via a pipe 540a. The pipe 540a is connected to the copper cold plate 510 via fitting 555a and aluminum radiator 520 via fitting 555b. The reverse bias system 560 is electronically connected at one end to the fitting 545 of the cold plate 510 and at a second end to the counter electrode 105.

System 500 can be modeled by the model 100 in FIG. 1. For example, the aluminum radiator 520 can correspond to the metal 110 in FIG. 1 while the copper cold plate 510 corresponds to the metal 115 in FIG. 1. As discussed in FIG. 1, the heterogeneous usage of metal materials such as aluminum and copper in the system 500 causes galvanic corrosion in the system 500. Galvanic corrosion causes a galvanic current in the system 500 and may be calculated or estimated using the Nernst equation to define the thermodynamic relationship between a galvanic current and the related corrosion/etching in the system. In some examples, as temperature of the system 500 increases during operation, the galvanic corrosion also increases. The reverse bias system 560 receives measurements from the current sensor 125 (coupled between the radiator 520 and the reservoir 530 which includes the counter electrode 105) and the current sensor 135 (coupled between the cold plate 510 and the radiator 520) to measure the galvanic currents and includes the power supply 120 to apply an external reverse bias voltage to the system 500. In some examples, the current sensor 125 measures the galvanic current between a first heat exchange component and the counter electrode 105 disposed in the pump/reservoir 530. For example, the current sensor 125 is positioned to measure the galvanic current across the fittings 545 of the copper cold plate 510 and the counter electrode 105. The reverse bias system 560 then applies the reverse bias voltage via the power supply 120 to reduce or prevent the galvanic current. Moreover, reducing the galvanic current can also prevent oxidation on the heat exchange components in the system 500, such as the aluminum radiation 520 and the copper cold plate 510.

In one embodiment, the reverse bias system 560 determines, based on a corrosion model for the liquid cooling system and the galvanic currents measured by the current sensors 125 and 135, a corrosion status of the liquid cooling system at a first time. In some examples, the corrosion status includes an amount of corrosion present in the system based on the material properties of the coolant and the measure galvanic current. The reverse bias system 560, using the corrosion status and the galvanic current, determines a reverse bias voltage to prevent corrosion in the liquid cooling system. For example, the reverse bias system 560 may determine a reverse bias voltage that would bring the corrosion rate to 0 μg/day.

FIG. 5 also illustrates a wire 552 (along which the current sensor 135 is disposed) that electrical connects the copper cold plate 510 to the aluminum radiator 520 so that these two heat exchange components are at substantially the same voltage potential. In this example, the wire 552 is coupled to the fitting 555a of the cold plate 510 and the fitting 555b of the radiator 520, but can be coupled anywhere so long as the wire 552 enables these two components to be at the same voltage potential. If other non-inert heat exchange components are present which also contact the coolant, then an additional wire can be used to connect that component with the radiator 520 and the cold plate 510. For example, if the reservoir 530 is made from a non-inert metal (which could be aluminum, copper, or some other metal), it too can be susceptible to corrosion. In that case, a wire can be added to the system 500 to connect the reservoir 530 to the aluminum radiator 520 or the copper cold plate 510 (and add another current sensor). However, the reservoir 530 could be made from an inert material (e.g., plastic or rubber) in which case it would not be susceptible to galvanic corrosion or oxidation, and as such, it would not prevent corrosion to electrically couple the reservoir 530 to the radiator 520 or the cold plate 510.

While FIG. 5 illustrates disposing the counter electrode 105 within the reservoir 530, this is just one suitable location. The counter electrode 105 can be disposed in any location of the system 500 so long as the counter electrode 105 is brought in contact with the coolant. For example, the counter electrode 105 could be disposed in a large tube through which the coolant flows. In one embodiment, the counter electrode only connects to the heat exchange components by wire.

FIG. 6 illustrates an equivalent circuit 600 for the cooling system in FIG. 5, according to one embodiment. The circuit 600 includes the current sensors A1-A3 and the power supply 120 which can form the reverse bias system 560. The circuit 600 illustrates that the power supply 120 is coupled at one end to M_{D} which represent the counter electrode 105. FIG. 6 also includes M_{A} which represents the cold plate 510, MB which represents the aluminum radiator 520 and M_{C} which represents any other or additional non-inert material that may be coupled in series (e.g., the pump or reservoir 530).

In another embodiment, there may be multiple M_{A}'s connected in parallel in implementations that have multiple copper cold plates 510. For example, the PCB 506 can support four chips 505 with four copper cold plates 510 for cooling the four chips 505.

FIG. 6 also illustrates resistances R1-R3 that represents the conductivity of the coolant in the liquid cooling system. The metals M_{A-C} can have different resistance values R1-R3 to the counter electrode M_{D}. Regardless of the different resistances R1-R3, using the control techniques above, the reverse bias system can apply a reverse bias voltage via the power supply 120 to reduce or prevent the galvanic current. Moreover, reducing the galvanic current can also prevent oxidation on the heat exchange components in the system.

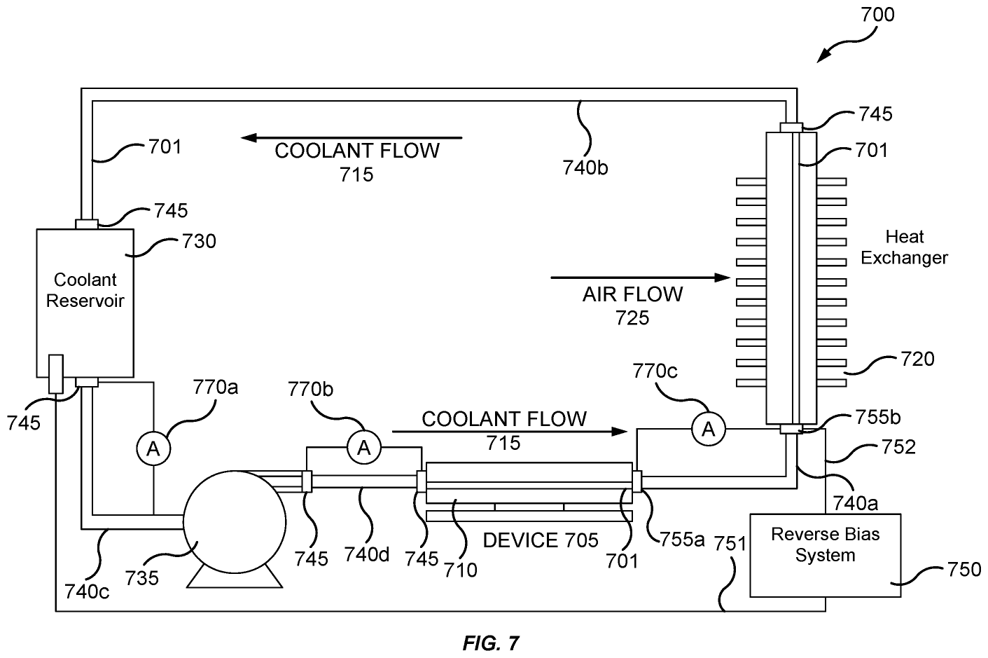

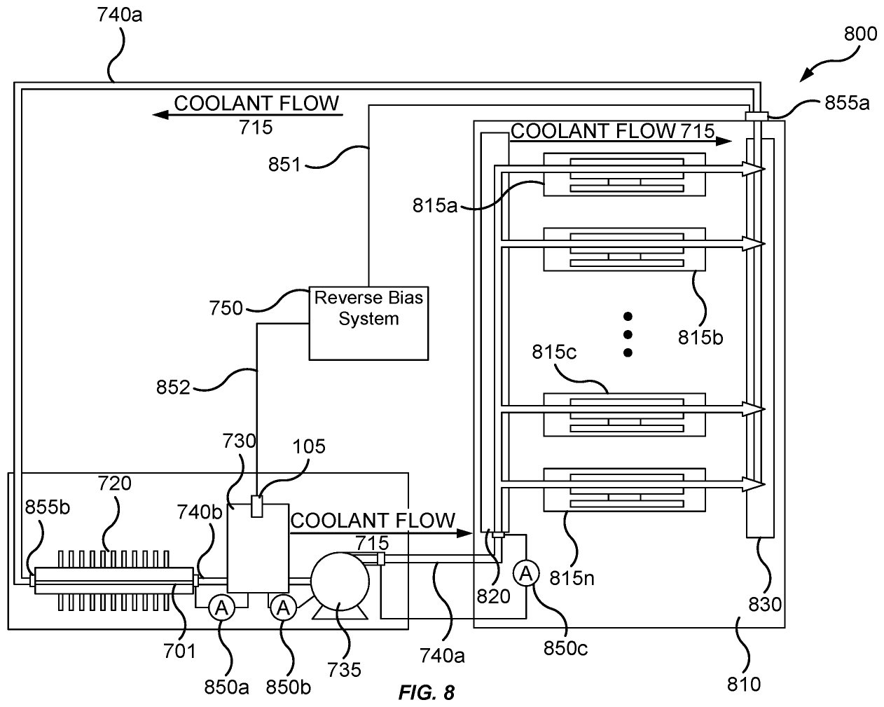

FIG. 7 illustrates a closed loop liquid cooling system 700, according to one embodiment. The system 700 is referred to a closed loop system since a liquid coolant 701 flows through each component of the system 700 in a closed loop. The embodiments described herein do not require that the various liquid cooling systems are arranged in closed loops. (For example, an open loop liquid cooling system is described in more detail in relation to FIG. 8.) The system 700 provides cooling to various electronic components in the system by circulating the liquid coolant 701 from heat producing electronic components to heat radiating components.

For example, the system 700 includes device 705 which produces heat. In some examples, the device is in integrated circuit (IC) chip (e.g., an application-specific integrated circuit (ASIC) chip) or other type of electronic/heat producing device which produces heat at a level that requires external cooling. For example, the device 705 may produce an amount of heat that would degrade a performance of the device 705 without heat mitigation via a cooling system associated with the device 705.

To provide heat mitigation or cooling to the device 705, the system 700 includes component 710 attached to the device 705 or otherwise positioned to provide heat exchange between the device 705 and the liquid coolant 701. The component 710 may include any type of heat exchanger which provides heat exchange and cooling to the device 705. In some examples, the component 710 is a cold plate which includes tubing embedded in a heat conductive material in the component 710, where the liquid coolant 701 flows through the tubing and absorbs heat from the device 705 via the heat conductive material. In some examples, the liquid coolant 701 flows as heated coolant from the component 710 to a component 720 where the liquid coolant 701 exchanges or radiates the heat absorbed at the component 710 into the component 720.

The component 720 may include any type of heat exchanger or radiator which provides for heat exchange/absorption from heated liquid coolant. For example, the component 720 may include a radiator, such as an air cooled aluminum radiator, which radiates heat from the component 720 to an airflow 725 which flows across and through various subcomponents of the component 720 (e.g., radiator fins etc.). The component 720 provides the liquid coolant 701, as a cooled coolant back to recirculation components of the system 700. For example, the liquid coolant 701 flows into a coolant reservoir 730 and is recirculated into the component 710 by a coolant pump system such as a coolant pump 735. The coolant pump 735 provides the liquid coolant 701 along the coolant flow 715 from the component 710 to the component 720, the coolant reservoir 730 and any other additional components typical to a liquid cooling system.

The liquid coolant 701 flows between the various components via conduits, tubing, or pipes such as pipe 740a, pipe 740b, pipe 740c, and pipe 740d. In some examples, the pipes 740a-740d are plastic piping or piping formed from other inert or non-reactive and non-conductive materials. The pipes are connected to the various components via fittings 745, fitting 755a, and fitting 755b. For example, the fitting 755a connects the pipe 740a to the component 710 and the fitting 755b connects the pipe 740a to the component 720. In some examples, the fittings 745, 755a, and 755b are formed from metallic or conductive materials, such that the fitting serve as electrical contacts as described in more detail herein.

While shown in FIG. 7 in a circular arrangement, the various components of system 700 may be positioned in various arrangements in relation to the other components of the system. Additionally, the components of the system 700 may be collocated on a structure (e.g., located on a single chassis or other base structure) or may be located at different locations. Moreover, the reverse bias system 560 discussed in FIG. 5 may be collocated with other components of the system 700 or remote from the component 710. In some examples, the reverse bias system 560 is positioned on a chassis or base structure independent of either the chassis or component 710. The reverse bias system 560 is connected to the system 700 via connection 751 to the counter electrode 105 and via connection 752 to the fitting 755b. The reverse bias system 560 can receive current measurements from the current sensors 770a-c and applying an external reverse bias voltage to prevent corrosion in the liquid cooling system, as described in more detail above. Additionally, although not shown, any components in the system 700 that are made from a non-inert material (e.g., are susceptible to corrosion) that contact the coolant may be connected electrically to each other so that these components have the same voltage potential.

FIG. 8 illustrates on open loop liquid cooling system 800, according to one embodiment. The system 800 includes the liquid coolant 701, the component 720, coolant reservoir 730, and coolant pump 735 which pumps the liquid coolant 701 through the system 800 along the coolant flow 715. In the system 800, cooling heat exchanges is provided to a plurality of heat producing electronic devices via a manifold system 810. The manifold system 810 includes a supply manifold 820 which provides liquid coolant received via the pipe 740a to arrangements 815a-815n. In some examples, each of the arrangements 815a-815n includes a component and a device (e.g., the component 710 and the device 705). In some examples, the liquid coolant 701 flows from the supply manifold 820 through a plurality of copper cold plates (or other copper heat exchangers) in the arrangements 815a-815n and heated liquid coolant 701 flows into the return manifold 830. The heated liquid coolant flows from the return manifold 830 the component 720 via the pipe 740a. The system 800 also includes the reverse bias system 560, where the reverse bias system 560 is connected to fitting 855a via a connection 851 and to the counter electrode 105 via a connection 852. The arrangement of system 800 in FIG. 8 is shown in a circular arrangement; however, the various components of the system 800 may be collocated or positioned in remote locations.

As described above, the liquid cooling systems, systems 700 and 800, are subject to various levels of corrosion which often causes several issues in the systems. For example with reference back to FIG. 7, the liquid coolant 701 may cause galvanic and other corrosion in any metallic components with which the coolant contacts or interacts. These corrosion sources may include any of component 710, component 720, coolant reservoir 730, the coolant pump 735, and the pipes 740 (if metallic). In some examples, as the system 700 corrodes, the corroded materials collect in the liquid coolant 701 which in turn lowers a heat exchange efficiency and thermal performance of the liquid coolant 701. For example, the liquid coolant 701 with large amounts of corroded material in suspended in the liquid will not exchange heat with the component 710 and component 720 at a same efficiency as a liquid coolant 701 without corroded materials. Additionally, corroded materials may cause clogs, blockages, or other reduced flow issues such that the liquid coolant 701 along the coolant flow 715 requires a higher energy output from the coolant pump 735 and provides lower amounts of exchange between the component 710, component 720 and the liquid coolant 701.

In some examples, corrosion in the system 700 also degrades the structural integrity of the metallic components, including component 710, component 720, and the fittings 745, 855a, and 855b. This degradation may cause the various components to decrease in performance. For example, the components 710 and 720 may not exchange heat as efficiently as designed. Additionally, the structural degradation may cause leaks to form in the system 700. For example, leaks may form in any of the components 710 and 720 and the fittings 745, 755a, and 755b. Leaks of the liquid coolant 701 require for the leaks to be repaired and for coolant to be refilled which increases the overall maintenance costs of the system 700.

To prevent or reduce corrosion in the system 700, the system may include several corrosion mitigation measures. For example, the system 700 may include metallic interactions with the liquid coolant 701. For example, the component 710, the component 720, and the various fittings may all be formed from a single metallic material, such as copper. In example where all of metallic interactions with the liquid coolant are copper, corrosion in the system 700 is reduced since there is no galvanic corrosion; however, copper is relatively heavy compared to other suitable materials (e.g., aluminum). This increased weight in limits the feasibility of fabricating and installing the system 700. Further, even if the components are the same metal, there are still susceptible to corrosion via oxidation.

In some examples, lighter weight heterogeneous materials may be used. For example, a mixture of copper components and aluminum components may be used in the system 700, which reduces the weight of the system 700. In some examples, the various aluminum components may include protective layers, such as an aluminum oxide layer between the liquid coolant 701 and the components themselves. For example, the component 720 may be an aluminum radiator that includes an aluminum oxide layer between the liquid coolant 701 and an aluminum body of the radiator. In some examples, the protective layers reduce corrosion in the system, but corrosion may still occur through protective layers and the thermal conductivity of the protective layers is lower than the surrounding materials.

Another example corrosion resistance measure includes increasing a resistance of the liquid coolant 701, such that corrosion via galvanic reactions is reduced. In some examples, corrosion inhibitors reduce corrosion, but increases maintenance costs and requires frequent liquid exchange or refill in order to keep the corrosion inhibitor at optimum levels in the liquid coolant 701. While each of the above solutions provide some measure of corrosion preventing in the system 700, corrosion may still be present in the system 700.

To provide efficient and effective corrosion prevention in the systems discussed in any of the figures above, the systems can include a reverse bias system such as reverse bias system 560 and current sensors 850a-c. As already described above, the reverse bias system 560 provides for corrosion prevention in the system by applying an external reverse bias. The reverse bias system described herein can be used to mitigate both galvanic corrosion and oxidation, or only galvanic corrosion in systems that are not susceptible to oxidation, or only oxidation in systems that are not susceptible to galvanic corrosion.

FIG. 9 illustrates a block diagram of a reverse bias system, according to one embodiment. The reverse bias system 560 may include a control system 901 embodied as computer or other electronic device which executes the functions of the reverse bias system 560 discussed above, and can perform the methods, including method 400 described herein. The control system 901 is shown in the form of a general-purpose computing device. The components of control system 901 may include, but are not limited to, one or more processing units or processors 905, a system memory 910, a storage system 920, a bus 950 that couples various system components including the system memory 910 and storage system 920 to processors 905, along with current sensors 125 and 135, power supply 120, and along with an external network interface 930. The external network interface 930 is connected to an external network such as the internet 960. In some embodiments, the reverse bias system 560 is distributed and includes a plurality of discrete computing devices that are connected through wired or wireless networking.

System memory 910 may include a plurality of program modules 915 for performing various functions related applying an external reverse bias voltage, described herein. The program modules 915 generally include program code that is executable by one or more of the processors 905. As shown, program modules 915 include a reverse bias module 911 and a reverse bias model module 912. In some examples, the program modules 915 may be distributed and/or cloud based applications/modules. Additionally, storage system 920 may include media for a corrosion model 921 and historical values 922, and other information. The information stored in storage system 920 may be updated and accessed by the program modules 915 described herein.

Additionally various computing components may be included to perform the methods described herein. For example, bus 950 represents one or more of any of several types of bus structures, including a memory bus or memory controller, a peripheral bus, an accelerated graphics port, and a processor or local bus using any of a variety of bus architectures. In some examples, such architectures may include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Further, the control system 901 typically includes a variety of computer system readable media. Such media may be any available media that is accessible by the control system 901, and it includes both volatile and non-volatile media, removable and non-removable media.

System memory 910 can include computer system readable media in the form of volatile memory, such as random access memory (RAM) and/or cache memory. The control system 901 may further include other removable/non-removable, volatile/non-volatile computer system storage media. In some examples, storage system 920 can be provided for reading from and writing to a non-removable, non-volatile magnetic media (not shown and typically called a “hard drive”). Although not shown, an optical disk drive for reading from or writing to a removable, non-volatile optical disk such as a CD-ROM, DVD-ROM or other optical media can be provided. In such instances, each can be connected to bus 950 by one or more data media interfaces.

As depicted and described above, system memory 910 may include at least one program product having a set (e.g., at least one) of program modules 915 that are configured to carry out the functions of embodiments of the invention. The control system 901 may further include other removable/non-removable volatile/non-volatile computer system storage media. In some examples, storage system 920 may be included as part of system memory 910 and may typically provide a non-volatile memory for the networked computing devices, and may include one or more different storage elements such as Flash memory, a hard disk drive, a solid state drive, an optical storage device, and/or a magnetic storage device.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

We claim:

1. A liquid cooling system comprising:
a first heat exchange component comprising a first non-inert metal forming a first electrode;
a second heat exchange component comprising a second non-inert metal forming a second electrode;
a counter electrode comprising an inert material;
piping configured to carry a liquid coolant, wherein the first and second heat exchange components and the counter electrode contact the liquid coolant;
a first sensor configured to measure a current flowing, or a voltage, between the first heat exchange component and the counter electrode;
a second sensor configured to measure a current flowing, or a voltage, between the first heat exchange component and the second heat exchange component; and
a control system coupled to the first and second sensors and configured to control a power supply electrically connected to the first heat exchange component and the counter electrode to generate a voltage that reduces or prevents at least one of galvanic corrosion or oxidation.

2. The liquid cooling system of claim 1, wherein the power supply generates a voltage that causes current to flow from the counter electrode to the first and second heat exchange components.

3. The liquid cooling system of claim 1, wherein the second non-inert metal is different from the first non-inert metal.

4. The liquid cooling system of claim 3, wherein the first heat exchange component is copper and the second heat exchange component is aluminum.

5. The liquid cooling system of claim 1, wherein the first heat exchange component is a cold plate configured to thermally couple to an integrated circuit and the second heat exchange component is a radiator.

6. The liquid cooling system of claim 1, further comprising:
a third component coupled to, or part of, the piping and contacting the liquid coolant, wherein the third component is electrically connected to the first heat exchange component or the second heat exchange component such that the first and second heat exchange components, and the third component are at a same voltage potential.

7. The liquid cooling system of claim 6, wherein the third component comprises a third non-inert metal that is different from the first and second non-inert metals.

8. The liquid cooling system of claim 6, wherein at least two of the first heat exchange component, the second heat exchange component and the third component are the same material.

9. The liquid cooling system of claim 1, wherein the voltage is a reverse bias and the first heat exchange component is coupled to a negative output of the power supply and the counter electrode is coupled to a ground output of the power supply.

10. The liquid cooling system of claim 1, further comprising:
a reservoir for storing the liquid coolant, wherein the counter electrode is disposed in the reservoir such that the counter electrode contacts the liquid coolant in the reservoir.

11. A method comprising:
measuring, using a first sensor, current flowing between, or a voltage between, a first heat exchange component and a counter electrode in a liquid cooling system, wherein the first heat exchange component comprises a first non-inert metal and the counter electrode comprises an inert material, wherein the first heat exchange component and the counter electrode contact a liquid coolant in the liquid cooling system;
measuring, using a second sensor, current flowing between, or a voltage between, the first heat exchange component and a second heat exchange component in the liquid cooling system, wherein the second heat exchange component comprises a second non-inert metal, wherein the second heat exchange component contacts the liquid coolant; and
generating a voltage to reduce or prevent at least one of galvanic corrosion or oxidation based on measurements from the first and second sensors.

12. The method of claim 11, wherein the voltage causes current to flow from the counter electrode to the first and second heat exchange components.

13. The method of claim 11, wherein second non-inert metal is different from the first non-inert metal.

14. The method of claim 13, wherein the first heat exchange component is copper and the second heat exchange component is aluminum.

15. The method of claim 11, wherein the first heat exchange component is a cold plate thermally coupled to an integrated circuit and the second heat exchange component is a radiator.

16. The method of claim 11, wherein the liquid cooling system comprises a third component contacting the liquid coolant, wherein the third component is electrically connected to the first heat exchange component or the second heat exchange component such that the first and second heat exchange components, and the third component are at a same voltage potential.

17. The method of claim 16, wherein the third component comprises a third non-inert metal that is different from the first and second non-inert metals.

18. The method of claim 11, wherein the generated voltage is a reverse bias.

19. The method of claim 18, wherein the first heat exchange component is coupled to a negative output of a power supply that generates the voltage and the counter electrode is coupled to a ground output of the power supply.

20. The method of claim 11, wherein the liquid cooling system comprises a reservoir for storing the liquid coolant, wherein the counter electrode is disposed in the reservoir such that the counter electrode contacts the liquid coolant in the reservoir.
